(19) United States
(12) Patent Application Publication
(10) Pub. No.: US 2019/0281251 A1
(43) Pub. Date: Sep. 12, 2019

(54) GLASS BACKPLANE AND TELEVISION WITH THE SAME

(71) Applicants: HONG FU JIN PRECISION INDUSTRY (ShenZhen) CO., LTD., Shenzhen (CN); HON HAI PRECISION INDUSTRY CO., LTD., New Taipei (TW)

(72) Inventors: NA WANG, Shenzhen (CN); CHENG-FA CHUNG, New Taipei (TW)

(21) Appl. No.: 15/969,405

(22) Filed: May 2, 2018

(30) Foreign Application Priority Data
Mar. 12, 2018 (CN) 201810200795.9

(51) Int. Cl. H04N 5/64; G02F 1/1333; H05K 7/20; B32B 17/06

(52) U.S. Cl. CPC H04N 5/64; G02F 1/133382; G02F 1/133308; H05K 7/20963; B32B 2457/20; G02F 2001/133314; G02F 2001/13332; B32B 2255/00; B32B 2307/412; B32B 17/06

(57) ABSTRACT

A television includes a glass backplane presenting a complex and combinational image. The glass backplane includes a first glass layer, an appearance image layer, and a second glass layer. The appearance image layer is composed by a first image layer and a second image layer. The second glass layer is a transparent glass. The appearance image layer is formed between the first glass layer and the second glass layer.

### FIELD

The subject matter generally relates to a glass backplane and a television with the same.

### BACKGROUND

In a television, a backplane is essential. In the prior art, most of the backplane are metal backplanes. An image on the metal backplane is formed by painting or applying a film with images. With the increasing demand for images on the backplanes, single-layer glass is also used as the backplane. However, the strength of such a single-layer glass backplane is weak and the images are simplistic.

Thus, there is room for improvement in the art.

### BRIEF DESCRIPTION OF THE DRAWINGS

Implementations of the present disclosure will now be described, by way of example only, with reference to the attached figures.

FIG. 1 is a cross-sectional view of an embodiment of a television according to the present disclosure.

FIG. 2 is a cross-sectional view of a glass backplane of the television of FIG. 1.

### DETAILED DESCRIPTION OF EMBODIMENTS

It will be appreciated that for simplicity and clarity of illustration, where appropriate, reference numerals have been repeated among the different figures to indicate corresponding or analogous elements. In addition, numerous specific details are set forth in order to provide a thorough understanding of the embodiments described herein. However, it will be understood by those of ordinary skill in the art that the embodiments described herein can be practiced without these specific details. In other instances, methods, procedures, and components have not been described in detail so as not to obscure the related relevant feature being described. Also, the description is not to be considered as limiting the scope of the embodiments described herein. The drawings are not necessarily to scale, and the proportions of certain parts may be exaggerated to better illustrate details and features of the present disclosure.

The disclosure is illustrated by way of example and not by way of limitation in the figures of the accompanying drawings. It should be noted that references to “an” or “one” embodiment in this disclosure are not necessarily to the same embodiment, and such references mean “at least one.”

The term “comprising” when utilized, means “including, but not necessarily limited to”; it specifically indicates open-ended inclusion or membership in the so-described combination, group, series, and the like.

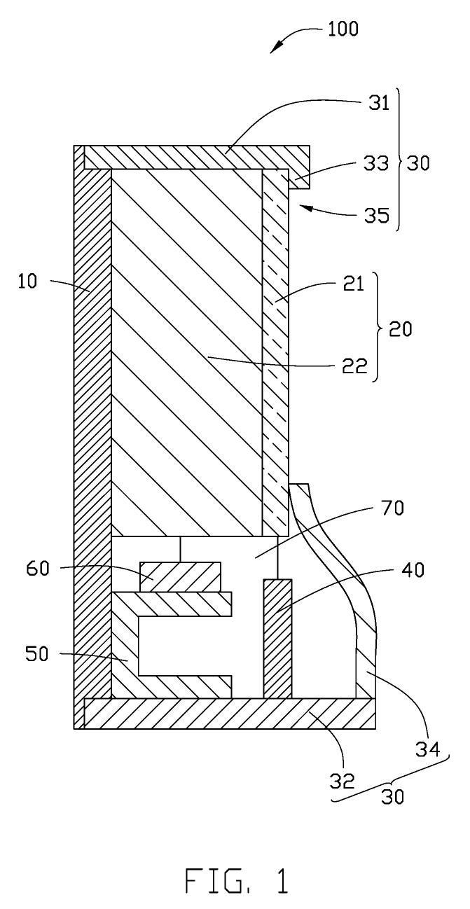

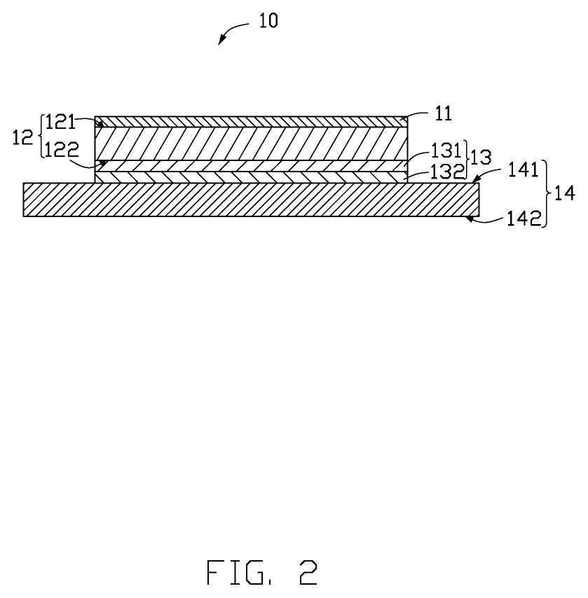

FIGS. 1-2 illustrate an embodiment of a television 100. The television 100 includes a glass backplane 10, a display unit 20, a frame 30, a driving printed circuit board 40, a heat dissipation element 50, and an optical printed circuit board 60. The display unit 20 being opposite to the glass backplane 10. The glass backplane 10 and the frame 30 cooperatively define a first receiving space 70. The display unit 20, the driving printed circuit board 40, the heat dissipation element 50, and the optical printed circuit board 60 are received in the first receiving space 70.

The glass backplane 10 includes an optical functional layer 11, a first glass layer 12, an appearance image layer 13, and a second glass layer 14. The optical functional layer 11 is formed on the first glass layer 12. The appearance image layer 13 is formed between the first glass layer 12 and the second glass layer 14.

The optical functional layer 11 is opposite to the display unit 20. In at least one embodiment, the optical functional layer 11 is a reflective layer.

The first glass layer 12 includes a first glass surface 121 and a second glass surface 122. The second glass surface 122 is opposite to the first glass surface 121.

The optical functional layer 11 is formed on the first glass surface 121.

The first glass layer 12 is a transparent glass.

The appearance image layer 13 includes a first image layer 131 and a second image layer 132. The first image layer 131 faces the second image layer 132.

A first part of the first image layer 131 is formed on the second glass surface 122 of the first glass layer 12. The first image layer 131 is formed on the second image layer 132. A second part of the second image layer 132 is formed on the second glass layer 14.

When the first image layer 131 is formed on the second image layer 132, the first image layer 131 and the second image layer 132 can form a combined or new image, so the appearance image layer 13 can be more diversified and more colorful. That is, the first image layer 131 and the second image layer 132 can make the glass backplane 10 have a more diversified and more colorful appearance.

The second glass layer 14 is a transparent glass. The appearance image layer 13 is visible through the second glass layer 14.

The second glass layer 14 includes a third glass surface 141 and a fourth glass surface 142. The fourth glass surface 142 is opposite to the third glass surface 141. The second image layer 132 is formed on the third glass surface 141. The fourth glass surface 142 can be planar or non-planar. Furthermore, a plurality of prominences can be formed on the fourth glass surface 142 to make image of the appearance image layer 13 be more complex.

In at least one embodiment, an area of the first glass layer 12 is less than an area of the second glass layer 14.

The display unit 20 includes a display screen 21 and a backlight module 22. The backlight module 22 is positioned between the glass backplane 10 and the display screen 21.

The display screen 21 can be a liquid crystal display or a plasma panel. In at least one embodiment, the display screen 21 is a liquid crystal display.

The frame 30 can protect the display unit 20, the driving printed circuit board 40, the heat dissipation element 50, and the optical printed circuit board 60.

The frame 30 includes an upper frame portion 31, a lower frame portion 32, a first front frame portion 33, and a second front frame portion 34. The upper frame portion 31 and the lower frame portion 32 are perpendicularly connected to opposite sides of the glass backplane 10. The lower frame portion 32 faces away from the upper frame portion 31. The first front frame portion 33 is parallel with the glass backplane 10 and perpendicularly connected to the upper frame portion 31. The second front frame portion 34 is perpendicularly connected to the lower frame portion 32 and faces away from the glass backplane 10. An opening 35 is defined between the first front frame portion 33 and the second front frame portion 34 to expose the display screen 21.

The driving printed circuit board 40 is positioned between the glass backplane 10 and the second front frame portion 34. The driving printed circuit board 40 is electrically connected to the display screen 21 to drive the display screen 21.

The heat dissipation element 50 is positioned between the glass backplane 10 and the driving printed circuit board 40. The heat dissipation element 50 can dissipate heat generated by the display unit 20.

The optical printed circuit board 60 is electrically connected to the backlight module 22 to drive the backlight module 22, and is positioned between the heat dissipation element 50 and the backlight module 22. In at least one embodiment, the optical printed circuit board 60 is positioned on the heat dissipation element 50.

With the above configuration, the television 100 uses two glass layers (the first glass layer 12 and the second glass layer 14) as the glass backplane 10, and the appearance image layer 13 is formed between the first glass layer 12 and the second glass layer 14. The appearance image layer 13 is composed of the first image layer 131 and the second image layer 132, so, (1) the first image layer 131 and the second image layer 132 can be independently designed to have a backplane that is more diversified and of more colorful appearance; and (2) the first glass layer 12 and the second glass layer 14 can enhance strength of the glass backplane 10.

It is to be understood, even though information and advantages of the present embodiments have been set forth in the foregoing description, together with details of the structures and functions of the present embodiments, the disclosure is illustrative only. Changes may be made in detail, especially in matters of shape, size, and arrangement of parts within the principles of the present embodiments to the full extent indicated by the plain meaning of the terms in which the appended claims are expressed.

What is claimed is:

1. A glass backplane, comprising:
a first glass layer;
an appearance image layer; and
a second glass layer; wherein, the second glass layer is a transparent glass, the appearance image layer is located between the first glass layer and the second glass layer.

2. The glass backplane of claim 1, wherein the appearance image layer comprises a first image layer and a second image layer, the first image layer is formed on the second image layer.

3. The glass backplane of claim 2, wherein a first part of the first image layer is formed on the first glass layer and a second part of the second image layer is formed on the second glass layer.

4. The glass backplane of claim 2, wherein the glass backplane further comprises an optical functional layer, the optical functional layer is formed on the first glass layer and keeps away from the first image layer.

5. The glass backplane of claim 1, wherein the second glass layer comprises a third glass surface and a fourth glass surface facing away from the third glass surface, the second image layer is formed on the third glass surface, and the fourth glass surface is a plane or a non-plane.

6. The glass backplane of claim 5, wherein the glass backplane further comprises a plurality of prominences, the plurality of prominences is formed on the fourth glass surface.

7. The glass backplane of claim 1, wherein the first glass layer is a transparent glass.

8. The glass backplane of claim 1, wherein an area of the first glass layer is less than an area of the second glass layer.

9. A television, comprising:
a glass backplane, the glass backplane comprising:
a first glass layer;
an appearance image layer; and
a second glass layer; wherein, the second glass layer is a transparent glass, the appearance image layer is located between the first glass layer and the second glass layer.

10. The television of claim 9, wherein the appearance image layer comprises a first image layer and a second image layer, the first image layer is opposite to the second image layer.

11. The television of claim 10, wherein a first part of the first image layer is formed on the first glass layer, a second part of the first image layer is formed on the second image layer, and the second image layer is formed on the second glass layer.

12. The television of claim 9, wherein the glass backplane further comprises an optical functional layer, the optical functional layer is formed on the first glass layer and faces away from the first image layer.

13. The television of claim 9, wherein the glass backplane further comprises plurality of prominences, the plurality of prominences is formed on the second glass layer and faces away from the second image layer.

14. The television of claim 9, wherein the television further comprises a display unit facing the glass backplane, the display unit comprises a display screen and a backlight module, the backlight module is positioned between the backplane and the display screen.

15. The television of claim 14, wherein the television further comprises a frame connected to the glass backplane, a driving printed circuit board, a heat dissipation element, and an optical printed circuit board; wherein the glass backplane and the frame cooperatively define a first receiving space, the display unit, the driving printed circuit board, the heat dissipation element, and the optical printed circuit board are received in the first receiving space.
